(19) United States
(12) Patent Application Publication
(10) Pub. No.: US 2007/0045719 A1
(43) Pub. Date: Mar. 1, 2007

(54) Multi-purpose semiconductor device

(75) Inventors: Chih-Hao Wang, Hsin-Chu (TW); Ching-Wei Tsai, Taoyuan City (TW); Chien Tai Chan, Taoyuan (TW); Min-Hwa Chi, Taipei (TW); Tahui Wang, Hsin-Chu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/244,463

(22) Filed: Oct. 6, 2005

Related U.S. Application Data
(60) Provisional application No. 60/713,791, filed on Sep. 1, 2005.

(51) Int. Cl. H01L 29/792

(52) U.S. Cl. 257/324; 257/405; 257/406; 257/E29.309

(57) ABSTRACT

A semiconductor device having at least two controllable states that can be connected to function as a binary memory device (e.g. a DRAM) or alternately as a multi-state (for example four levels) memory device. The device can also be arranged to function substantially as a non-volatile device. The device is formed substantially as a MOSFET that further includes a layer of high-k dielectric between the gate dielectric and the gate electrode to provide one, two, or three charge trap positions. The three charge trap positions allow three different voltage levels plus “0” volts to write the four possible states for two bits (“0-0”, “0-1”, “1-0”, and “1-1”). When in a read mode, a non-destructive current through the transistors varies depending on the voltage level used to write to the transistor and represents the different bit combinations available with 2 bits.

This application claims the benefit of U.S. Provisional Application No. 60/713,791, filed on Sep. 1, 2005, entitled Multi-Purpose Semiconductor Device, which application is hereby incorporated herein by reference.

### TECHNICAL FIELD

The present invention relates to a single semiconductor device that may function as either a logic device or a memory device, and more particularly to such a device that can selectively be driven or placed in more than just an ON or OFF (binary) state when operating as a memory device.

### BACKGROUND

The ever increasing demand for more complex yet smaller and smaller integrated circuits and memories continues to require the existing technology to approach and exceed various physical boundaries related to materials and fabrication processes. As an example, only a few years ago etching or patterning of a layer of aluminum was the dominant technology for forming interconnections or conductors in an integrated circuit chip. However, due to the need for lower resistance and unintended capacitance, copper lines or connectors deposited by a damascene process is now usually the technology of choice.

Today, the core or basic semiconductor device of an integrated circuit (such as for example FETs and capacitors) are becoming so small that often they will not function properly. For example, as the dimensions of a device such as transistors move into the nanometer (nm) range, the device begins to experience undesirable quantum effects such as electron tunneling through the gate oxide and excessive magnetic and corresponding electric fields that result from small spacings. Many of the typical manufacturing processes such as lithography, etching, deposition, etc. are now also approaching their theoretical limits. Consequently, transistors are often “leaky” as the electronic charge on the gate leaks through the gate oxide and current flows between the source and drain. Consequently, as CMOS scaling downward continues with thinner oxides, the required stand-by power increases to intolerable levels as a result of direct tunneling current or leakage through the oxides.

More specifically, as one example, DRAM cells are traditionally formed by one transistor and one capacitor. The capacitor stores a charge, and the transistor operates as a switch to allow the stored charge to be written to and/or read. To improve the capability of sensing or reading a cell fabricated according to this existing technology, it is necessary to increase the capacitance. Since small size is always important, simply increasing the area or size of the capacitor is not acceptable. Therefore, an increase in capacitance is accomplished by using stack or trench capacitors and/or using a high-k dielectric in the capacitor.

Downward scaling of the traditional one transistor, one capacitor DRAM is approaching its limit. For example, attempts to scale down the capacitor by increasing the dielectric constant or increasing the aspect ratio of a stack capacitor or trench capacitor results in processing difficulties. Likewise, reducing the channel length and/or oxide thickness (to improve access time) results in greater leakage current, which in turn reduces the retention time of the stored charge.

Flash memory cells are another example of devices that are being scaled to smaller and smaller size. A flash memory cell with a floating gate is presently the preferred device for providing NVM (non-volatile memory). The cell typically has 2 states (representing logic states of “1” and “0”) and is programmed by injecting charge (e.g.>10 thousand electrons) into the floating gate. When the floating gate has no net charge, the cell threshold voltage (V_{T}) is low and the cell current is high. When the floating gate is injected with electrons (high V_{T}), the cell threshold voltage is increased and the cell current is low.

Conventional floating-gate flash memory presents fundamental limitations such as non-scalable Si/SiO₂ energy barrier (leading to higher voltage for program/erase operations), floating-gate-to-drain coupling, and coupling between the floating-gates of adjacent cells, etc. Thus, the downward scaling of a conventional floating-gate flash memory may end at about a 90 nm feature size.

Recently, “nano-crystal” floating-gate flash memory cells embedded in the gate oxide (using Si nano-crystals to replace the continuous poly-Si floating-gate) have been used, and may extend the scaling limits to less than 90 nm. This type of cell has increased retention, thinner tunnel-oxide, lower operating voltage, and fast program/erase characteristics. Another type of flash memory uses SONOS (silicon, oxide, nitrogen, oxide, silicon) so that traps are formed in the nitride for charge storage. The cell also provides advantages of process simplicity, better cell scalability, low voltage operation, less coupling between adjacent charge storage layer, and less drain-induced turn-on.

A flash memory cell with nano-crystal Si replacing the floating-gate may extend the scaling limits to 45 nm. However, these small “nano-crystal” floating gate memory cells have new limitations. These new limitations include a small Vₜ shift (between program and erased states) and fluctuations of electrical parameters. These parameter fluctuations are related to the variations of nano-crystals size in a range of less than 10 nm. The SONOS-type cell may extend the scaling to values less than 65 nm, but some major issues still exist, such as slower program/erase and charge retention. The slower program/erase is related to the barrier height of the oxide. The retention time is related to the relaxation of charge storage traps and will decrease with shorter channel length as the number of stored electrons is scaled down.

The nano-crystal floating-gate device has also been used as a single-electron memory device. When used in this manner, very small scaling is possible by limiting the storage to only one small conducting “island” (referred to as a storage dot, and typically made of Si or Ge nano-crystal) or a small nitride island of traps embedded in the gate-oxide of a MOSFET. However, to operate in this manner, the cell is designed small in size with sufficient sensitivity to detect the effect of the transfer of a single electron. This is in contrast to the usual design of the floating-gate flash memory cell with no single-electron sensitivity (i.e. continuous charge transfer). In order to design a cell with high sensitivity, the storage dot needs to be in the small nanometer range (e.g. <10 nm) with low enough capacitance to overcome charge fluctuations due to thermal energy at room temperature that are less than a single electron level. The channel width also needs to be small enough (comparable to the size of the storage dot) to significantly affect the I_{d} (drain current)-V_{g} (gate voltage) relationship. Therefore, the single-electron memory cell is inherently suitable for scaling. Further, for maintaining single-electron sensitivity, the tunnel-oxide (between the channel and storage dot) and control-gate-oxide (between the storage dot and control gate) is currently approximately 30 Å (angstroms) to allow easier tunneling with single-electron sensitivity, and approximately 300 Å (angstroms) for smaller storage dot capacitance. The program and/or erase voltage is about 15 volts, which is comparable to conventional high-voltage operations for flash memory. Consequently, the thicker control gate-oxide results in a poor coupling ratio (0.1) between V_{g} and the potential of the storage dot. This means that a relatively large voltage is needed for program/erase operations. The thinner tunnel oxide also leads to poor charge retention (on the order of a few hundredths of a second). However, retention time can approach one or two hours by using nitrided Si nano-crystals as the storage dots. The single-electron memory cell can be fabricated with conventional CMOS logic processes with extra steps. As will be appreciate by those skilled in the art, the single electron memory device and its storage dot must be in the nano-meter range if it is to have sufficient sensitivity to detect single-electron effects and overcome charge fluctuations due to the thermal energy that exists at room temperature. Thus, lithography and process variations will set the fundamental limits. The thicker control gate-oxide leads to a poor coupling ratio approximately (0.1) from V_{g} to the potential of the storage dot. Further, a relatively high voltage is needed for program/erase operations. Consequently, the presently available single-electron memory cells are not as non-volatile as conventional flash memory, and are not as fast to program/erase as a DRAM. In addition, the cell with single-electron sensitivity usually has a poor current drive capability and, therefore, is not as useful for logic applications as conventional CMOS.

Therefore, new devices and/or fabrication techniques are necessary if goals for stable yet smaller circuits are to be reached.

Less expensive methods of scaling memory devices would be advantageous.

### SUMMARY OF THE INVENTION

These and other problems are generally solved or circumvented, and technical advantages are generally achieved, by embodiments of the present invention, which disclose a semiconductor device and fabrication methods. The semiconductor device comprises a gate dielectric layer of a high-k material for providing one or more single electron or hole trap positions. Selectively controlling the state of the multiple single electron or hole trap positions allows for the device to conduct current at different levels or magnitudes. Thus, by reading the magnitude of the current, the state of the device can be determined. More specifically, the semiconductor device comprises a substrate such as silicon or SOI (silicon-over-insulator) with a surface that includes at least two doped source/drain regions, which define a channel region between the source/drain regions. A gate structure having a selected length no greater than about 200 nm and a selected width no greater than about 100 nm is used with a 65 nm feature size. Smaller gate dimensions will allow feature sizes on the order of 45 nm. A first gate dielectric layer is formed of silicon oxide (SiO₂) or silicon oxynitride typically having a thickness of less than about 10 Å (angstroms). The gate dielectric layer is located on the surface of the substrate and over the defined channel region. A second dielectric layer formed of a high-k material, preferably having a dielectric constant greater than 7, is formed over the first dielectric material. The charge on the gate dielectric is determined by the number of single electrons or hole trap levels or positions in the high-k dielectric, and will vary with the thickness of the high-k dielectric layer. The number of electron or hole trap positions (i.e. the charge) will in turn determine the number of operational states that are available for use in the device. As an example only, a high-k dielectric layer having a thickness of about 5 Å (angstroms) will typically have a single electron or hole trap position or level, and will support binary or two states (for example ON or OFF). However, a thickness or about 10 Å (angstroms) can provide at least two trap positions, which allows for three states (for example OFF, first level ON, and second level ON). Similarly, a thickness of about 15 Å (angstroms) can provide at least three trap positions or levels, which means the device will have four possible states (OFF, first level ON, second level ON, and third level ON). A gate electrode covers the second dielectric layer and will be connected to the read and write gate voltages.

According to another embodiment, by increasing the thickness of the gate dielectric to about 30 Å (angstroms), the electron tunneling can be substantially reduced or eliminated such that the device can function substantially as a non-volatile or flash type memory.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### DESCRIPTION OF THE DRAWINGS

For a more complete understanding of the present invention, and the advantages thereof, reference is now made to the following descriptions taken in conjunction with the accompanying drawing, in which:

FIG. 1 discloses the device of the present invention according to a first embodiment wherein a high-k dielectric layer traps a single electron to provide a two state or binary device;

FIG. 2 illustrates a second embodiment of the invention wherein two electrons or hole trap levels are provided for a three state device;

FIG. 3 provides three trap electron or hole levels or positions for a four state devices;

FIG. 4 is similar to FIG. 3B except that it includes a thicker gate dielectric such that the device can function substantially as a non-volatile memory or flash memory; and

FIG. 5 illustrates the change in current levels of a MOSFET device as “single” electrons escape or are de-trapped from the high-k gate dielectric layer.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

According to the present invention, there is described a semiconductor device that can function as a logic transistor, a binary memory cell with high charge retention characteristics and consequently a very low refresh rate. The device can also function as a multilevel single electron memory cell, or a memory with a very long retention that approaches the requirements for a flash memory.

As is discussed in detail below, the semiconductor device of this invention is a unique MOSFET with a high-k gate dielectric that traps single electrons (or single holes) at a plurality of levels. It is believed that the device may be able to define up to at least ten different levels. Furthermore, due to the discrete nature of trapped charge emissions, the charge emission time can be clearly measured. This measurement serves to identify the physical path that the charge takes as it escapes or leaves the gate dielectric (i.e. de-trapping).

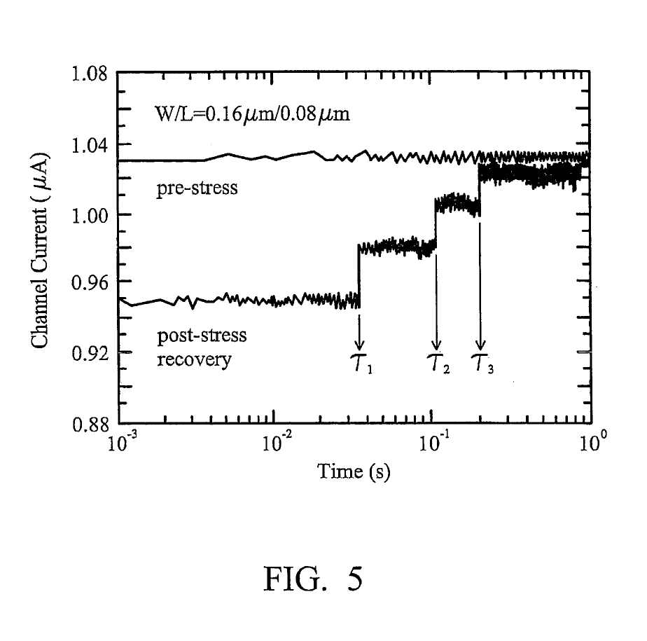

For example, referring now to FIG. 5, there is a graph showing test results of the current changes over time of a high-k nMOSFET having gate dimensions of W/L=0.16 μm/0.08 μm that was charged with a gate voltage V_{g} of about 0.7 volts for 100 ms. This voltage injects electrons into the high-k dielectric gate layer where they are temporarily “trapped”. After the electrons are injected, the drain current, which is identified as the channel current (in μA) in FIG. 5, is measured with a gate voltage (V_{g}) of between 0.25 and 0.55 volts and a drain voltage (V_{D}) of about 0.2 volts. As shown in the example of FIG. 5, there are four distinct current levels, which increase in steps over time and then saturates at a level approximately equal to the pre-charge level. Further, each current level corresponds to a “single” electron escaping or “de-trapping” from the high-k dielectric as indicated by τ₁, τ₂, and τ₃. It should also be noted that the amount of time that it takes for each electron to escape or “de-trap” increases as the gate voltage (V_{g}) increases.

The observed longer electron emission time with larger Vg suggests the dominant path of charge emission is toward the Si substrate. As will be appreciated by those skilled in the art, there are three possible paths for electron de-trapping. Namely, (1) the Frenkel-Poole (F-P) emission path, (2) a SRH (Shockley-Read-Hall: A process for electrons or holes to gain or loss energy through traps) like thermally-assisted-tunneling (TAT) path that is toward the gate electrode, and (3) TAT toward the Si substrate. The F-P de-trapping path is ruled out since the activation energy for the F-P mechanism should be equal to the trap energy, or about 1 eV, yet the extracted E is only 0.18 eV. The SRH de-trapping path is also ruled out since a larger Vg would accelerate the electron toward the gate electrode resulting in a shorter emission time. However, the observed emission time is just the opposite. Therefore, the temperature dependence with extracted activation energy of 0.18 ev confirms that the charge emission is the thermally assisted tunneling (TAT) path toward the substrate. A more detailed discussion of the de-trapping characteristics is provided in the paper entitled “Single-Electron Emission of Traps in HfSiON As High-k Gate Dielectric for MOSFETs”. Published by IEEE, International Reliability Physics Symposium (IRPS) 2005. This paper is incorporated in its entirety herein by reference.

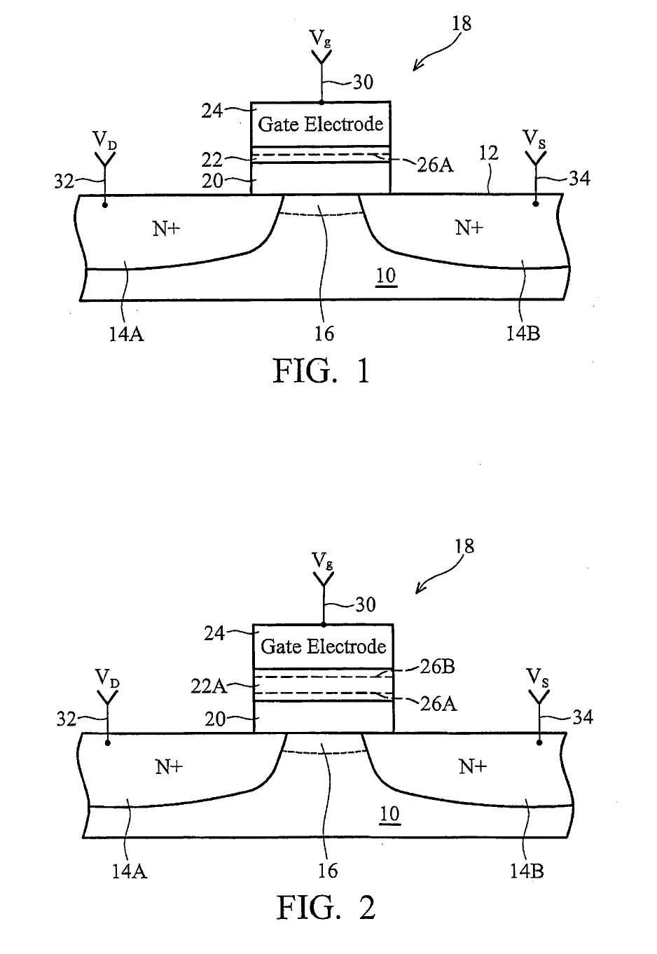

Referring now to FIG. 1, there is illustrated a first embodiment of the invention comprising a MOSFET having a feature size on the order of 65 nm or less. It is believed, however, that the invention should allow the fabrication of devices having a feature size as small as 45 nm or less. As shown, there is a substrate 10 defining a top surface 12. Substrate 10 may be formed of a suitable semiconductor material such as a SOI (silicon-on-insulator) or on a bulk silicon. Substrate 10 includes at least two doped regions such as the N+ doped regions 14a and 14b representing for example source and drain regions. The source and drain regions 14a and 14b may, for example, be used in a MOS (metal oxide silicon) semiconductor structure including a CMOS structure. MIS (Metal Insulator Silicon) may also be used. Regions 14a and 14b, such as used in FETs of a MOS device, are located on each side of the channel region 16. A gate structure 18 is formed on surface 12 and over the channel region 16. According to the embodiment of FIG. 1, the gate structure 18 comprises a gate dielectric 20, such as silicon oxide or SiON. According to this embodiment, the gate may have a width of about 0.2 μm and preferably about 0.16 μm or less and a length of about 0.1 μm and preferably about 0.08 μm or less. The dielectric 20 has a thickness on the order of about 10 Å (angstroms) or less, but as will be discussed later and for different types of applications, other thicknesses are also acceptable. In addition to the gate dielectric 20 and according to the invention, gate structure 18 further includes a high-k dielectric layer 22 having a selected thickness that is less than about 50 Å (angstroms), and is formed on top of the gate dielectric 20. Also as shown, a gate electrode 24 typically of a doped polysilicon material is formed on top of the high-k dielectric 22. In the embodiment shown, the gate electrode polysilicon material may be doped with an n-dopant material such as boron. The high-k dielectric layer 22 is selected to have a dielectric constant greater than about 7 and may be formed from suitable materials such as a hafnium based or aluminum based material. For example, a suitable hafnium based material is HfSiON (hafnium silicon oxy nitride), or an aluminum based material such as AlO2, HfAlO, HfAlON, HfAlSiON.

To assure at least a single electron (or a single hole) trap position or level as represented by dotted line 26a, the thickness of the high-k dielectric 22 should be at least about 3 Å (angstroms) and no greater than 10 Å (angstroms). Preferably dielectric 22 should be about 5 Å (angstroms). Therefore, the device will be a binary or two bit device having a “0” state with nothing in the trap level, or a “1” state with a charge in the trap level. However, as discussed below, if the device is to provide two charge levels plus a “0” level (i.e. three bits), the thickness should be at least about 6 Å (angstroms), no greater than 20 Å (angstroms), and preferably about 10 Å (angstroms). For three charged levels plus a “0” level (i.e. four bits), the thickness should be at least about 9 Å (angstroms), no greater than 30 Å (angstroms), and preferably about 15 Å (angstroms). As will be discussed below, the described device may be configured for different types of operation including various types of memories as well as logic devices. In addition, to facilitate the single electron trap levels, nano-crystals may be included in the high-k dielectric layer.

According to one embodiment, the device may be configured as a logic transistor or FET having a very small channel width and length. The exact same device may also function as a memory cell. The high-k gate oxide material is necessary to reduce gate current leakage for 45 nm feature sizes and smaller. The high-k material also serves as electron traps for charge storage in memory cell. However, both transistors with a thinner gate-oxide and transistors with thicker gate-oxide can be used as memory cells. The following illustrations discuss transistors with a HfSiON gate-oxide of 16 Å (angstroms) EOT. The operation voltage of a memory device may be different from that of a logic circuit.

In order for a logic transistor to be sensitive enough to detect a single-electron effect, the channel width and length must be small (i.e. in the nano-meter range). As mentioned above, tests of single-electron effects for a 65 nm feature size transistor with a gate width to length ratio W/L of 0.18 μm/0.08 μm suggests that even greater sensitivity will be present in transistors with a 45 nm feature size and smaller. Therefore, it will be appreciated that larger size transistors have weaker single-electron effects on the drain current. Further, the high-k gate material such as (HfSiON) should be fabricated with the minimum achievable density of electron traps for multibit storage. State of the art atomic-layer-deposition (ALD) is now commercially available for such applications. The high-k dielectric constant provides a large capacitance coupling (between the gate and the traps) as well as a longer distance that the trapped electrons must tunnel through as they move toward the transistor gate. This is an advantage for memory operations at low-voltage. The large capacitive coupling provides efficient gate control of the trap potential for ease of good electron mobility for logic transistors, and is also important for low-voltage operation (e.g. 1.2 volts of Vg and a coupling constant of about 0.7). This results in about 0.9 volts across the 10 Å (angstroms) bottom oxide with a significant tunneling current. Therefore, most trapped electrons are close to the interface of the high-k and the bottom oxide. The longer physical distance or thickness of the high-k material from the trapped electrons to the gate than to the channel also provide advantages for charge retention. As discussed above, the main path of a charge leak will be through the bottom oxide, and therefore, a positive gate bias can increase retention significantly (e.g. up to several minutes). Thus, all goals for design optimization for a memory application are comparable to the goals for design optimization for logic transistors. The common goals allow maximization of logic and memory technologies.

According to another embodiment, the logic transistor functions as a multilevel or bit single transistor DRAM by using the single electron effect. A lower voltage is applied in this embodiment to cause a slower single-electron “de-trapping” or emission effect on the transistor drain current. Further, as was discussed above, during testing, as each electron is de-trapped a step increase of the transistor drain current occurs. Further, as also discussed above the multiple states or bits can be determined by measuring the drain current. Therefore, as will be discussed in greater detail hereinafter, writing to the device at multiple levels simply requires the gate voltage to be biased or set at different levels to determine the number of electron trap levels in the high-k dielectric.

It will also be appreciated that charge retention may be increased by two techniques. The first technique is based on “counter balanced tunneling probability”. More specifically, by applying a positive V_{g} (e.g. 0.55 volts and V_{D} at 0 volts), this can result in a re-fresh time up to one second. The trapped electrons tunneling probability toward the substrate and gate are dynamically counter balanced for good retention. The second technique is based on “reduced tunneling” and is accomplished by connecting V_{g} to 0 volts so that the channel is in depletion. Thus, there is a reduced tunneling probability of trapped electrons tunneling toward the gate due to a lower V_{g} and reduced tunneling toward the channel or gate due to no available states in band-gape for tunneling. This, of course, results in good retention.

It will also be appreciated that the multibit operation can be converted to a one bit (i.e. binary) operation by writing to more than one trap level, and then measuring more than one electron transfer between the trap levels as a single reading. This will provide longer margin of detection.

According to still another embodiment, the device can serve substantially as a non-volatile memory cell. It should be noted the retention time of the transistor can be significantly boosted with a thicker bottom oxide approximately (e.g. 25 A for 2.5 volts). There is a trade-off, however. Namely, that the switch transistor will have a larger cell size with weaker single-electron effects and higher operating voltage to program and erase. Though the single-electron effect is weaker, it may still be operational by utilizing more than one electron levels to increase the drain current for larger margin of detection.

As discussed above, reducing or scaling to smaller and smaller sizes is a major consideration for all semiconductor devices. The present invention offers further opportunities for reducing the size of semiconductor devices. For example, and referring again to FIG. 1, the width of the gate structure 18 is no greater than about 200 nm (preferably about 160 nm) and the length is no greater than about 100 nm (preferable 80 nm) for a 65 nm feature size device. Preferably, the length of the gate structures is less than about 45 nm and the width of the gate structures is less than about 100 nm.

Referring now to FIG. 2, there is illustrated another embodiment of the present invention that is the same as the embodiment described in FIG. 1 except the high-k dielectric layer 22a is sufficiently thick to provide both first and second electron or hole trap levels or positions as indicated by dotted lines 26a and 26b. The dielectric layer 22a should be no less than about 10 Å (angstroms) in thickness if two charge trap levels (i.e. two electron or charge trap levels) are required. It is noted that because of the similarity of the two embodiments, the reference numbers in FIG. 2 are the same as the reference numbers of FIG. 1 except for the high-k dielectric 22a and the addition of the second charge trap position or level 26b. Further, as was discussed above, nano-crystals can also be included in the high-k dielectric of this embodiment.

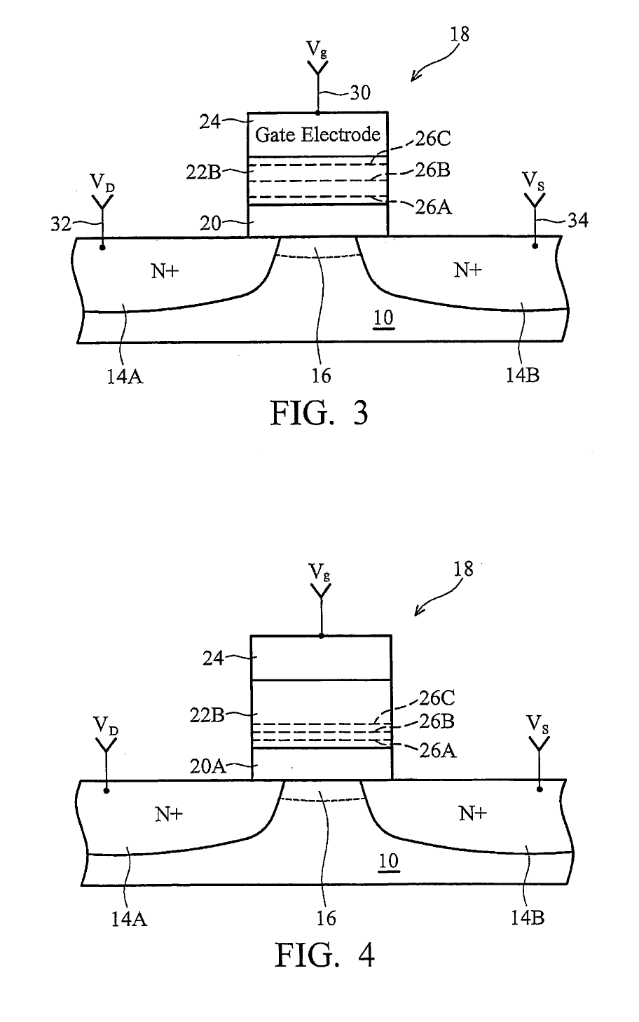

Similarly, FIG. 3 illustrates a third embodiment that is similar to the second embodiment and provides first, second, and third charge trap positions as indicated by dotted lines 26a, 26b, and 26c. As was the case with FIG. 2, the reference numbers of FIG. 3 are also the same as for FIG. 1 except for the high-k dielectric 22b and the additional charge trap levels. The high-k dielectric for the embodiments of FIG. 3 has a thickness of about 15 Å (angstroms) to provide three electron or hole trap levels, and may also include nano-crystals.

Referring collectively to FIGS. 1, 2, and 3, there is also included representative circuit connections to the devices. More particularly, there is shown a gate voltage (V_{g}) connection 30 to the gate electrode 24, a drain voltage (V_{D}) connection 32, and a source voltage (V_{S}) connection 34 typically connected to ground. As was discussed, the semiconductor device of this invention may function or operate in several different modes. For example, the device as shown in the figures may operate as a basic logic device such as an FET. Alternately, dependent upon the number of hole trap or electron trap positions (i.e. one, two, three, or more charge levels) the device may function substantially as a DRAM cell, having a low refresh period and having multiple storage states, such as four states, by designating four different gate voltages V_{g} to write to the driver. For example, assuming the V_{D} connection 32 is connected to “0 volts” as a first write voltage V_{g}. A V_{g} of 0 volts will not even fill the first electron or hole level and represents writing “0-0” to the device, a second write voltage V_{g} of 0.5 volts will fill the first charge level and represents writing “0-1”, a third voltage of 0.6 volts will fill the first and second charge levels and represents writing “1-0”, and a fourth write voltage of 0.7 volts will fill all three charge levels and represents writing “1-1” to the device. Depending upon the voltage used to write to the cell and the charge levels, the magnitude of current through the device during a read cycle will vary. For example, to read the device, a gate voltage V_{g} of 0.3 volts is applied to the device along with a drain voltage V_{D} of about 0.2 volts. Thus the device is turned on, and the non-destructive current magnitude between the source and drain as controlled by the gate voltage used to write to the device can be read in about 1 microsecond. Although the device functions somewhat slowly for a DRAM type device, it is extremely power efficient, (i.e. ultra low power usage), it operates at very low voltages, it can tolerate a very long period between refresh periods (about 1 second), and it can be scaled to very small dimensions. Alternately, the device can also function as a simple binary device by using more of the electron levels or hole positions that represent a “0” or a “1” bit. To operate in this mode, for example, “0” volts and the largest gate voltage (0.7 volts) can be used to respectively write either a “0” or a “1” bit to the device. As was the case discussed above, the device is somewhat slow, but it is still an efficient (ultra low power usage) device that uses low source, drain, and gate voltages that allows a long period between refresh and that may be scaled to very small dimensions.

Referring now to FIG. 4, there is illustrated another embodiment of the invention substantially similar to the device of FIG. 3, except the thickness of the gate dielectric 20a is increased to about 30 Å (angstroms) (the gate dielectric 20a is equal to or greater than 20 Å (angstroms). Therefore, with the thick gate dielectric 20a of 30 Å (angstroms), electron tunneling is significantly reduced. This results in an excellent, if not indefinite, retention time such that the device can operate almost as a non-volatile I/O (input/output) transistor.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the semiconductor devices or methods and steps described in the specification. As one of ordinary skill in the art will readily appreciate from the disclosure of the present invention, semiconductor devices, methods, or steps, presently existing or later to be developed, that perform substantially the same function or achieve substantially the same result as the corresponding embodiments described herein may be utilized according to the present invention. Accordingly, the appended claims are intended to include within their scope such semiconductor devices, methods, or steps.

What is claimed is:

1. A semiconductor device having at least two controllable states comprising:
a substrate having an active surface;
at least two doped regions formed in said active surface;
a channel region defined between said at least two doped regions; and
a gate structure having a selected width and a selected length, said gate structure comprising;
a gate dielectric having a selected thickness and located on said active surface of said substrate and over said channel region,
a high-k dielectric over said gate dielectric having a thickness selected to provide at least one electron or hole trap level, and
a gate electrode over said high-k dielectric.

2. The semiconductor device of claim 1 wherein said thickness selected for said high-k dielectric provides one electron or hole trap level.

3. The semiconductor device of claim 2 wherein said thickness of said high-k dielectric is less than about 10 Å (angstroms).

4. The semiconductor device of claim 1 wherein said thickness selected for said high-k dielectric provides two electron or hole trap levels.

5. The semiconductor device of claim 4 wherein said thickness of said high-k dielectric is less than about 20 Å (angstroms).

6. The semiconductor device of claim 4 wherein said thickness selected for said high-k dielectric provides three electron or hole trap levels.

7. The semiconductor device of claim 6 wherein said thickness of said high-k dielectric is less than about 30 Å (angstroms).

8. The semiconductor device of claim 1 wherein said width of said gate structure is no greater than about 200 nm and said length of said gate structure is no greater than about 100 nm.

9. The semiconductor device of claim 8 wherein said length is less than about 45 nm.

10. The semiconductor device of claim 1 wherein said high-k dielectric has a dielectric constant of greater than 7.

11. The semiconductor device of claim 1 wherein said selected thickness of said high-k dielectric is less than 50 Å (angstroms).

12. The semiconductor device of claim 1 wherein said high-k dielectric is made of a material selected from the group consisting of a hafnium based material and an aluminum based material.

13. The semiconductor device of claim 1 wherein said high-k dielectric includes nano-crystal structures.

14. The semiconductor device of claim 12 wherein said hafnium based material is nitrogen containing hafnium silicate.

15. The semiconductor device of claim 1 wherein said gate dielectric is a layer of silicon oxide having a thickness equal to or less than about 10 Å (angstroms).

16. The semiconductor device of claim 1 wherein said gate dielectric is a layer of silicon oxynitride having a thickness of equal to or less than about 10 Å (angstroms).

17. The semiconductor device of claim 1 wherein said gate dielectric is a layer of silicon oxide having a thickness equal to or greater than about 30 Å (angstroms) such that said device functions substantially as a non-volatile memory device.

18. The semiconductor device of claim 1 wherein said device functions as a memory cell having a refresh time of less than about 1 second.

19. The semiconductor device of claim 1 wherein said gate electrode is electrically connected to first and second different voltages such that said device functions as a logic device in response to said first voltage and as a memory device in response to said second voltage.

20. The semiconductor device of claim 1 wherein said device is a MIS (metal insulator silicon) device.
